(19) United States
(12) Patent Application Publication
(10) Pub. No.: US 2026/0221939 A1
(43) Pub. Date: Jul. 30, 2026

(54) VOLTAGE-CONTROLLED RC OSCILLATOR AND METHOD FOR GENERATING A CLOCK SIGNAL

(71) Applicant: Robert Bosch GmbH, Stuttgart (DE)

(72) Inventors: Chinwuba Ezekwe, Albany, CA (US); Mahdi Rajabzadeh, Muenchen (DE); Mourad Elsobky, Reutlingen (DE); Xinyu Xing, San Jose, CA (US)

(21) Appl. No.: 19/453,611

(22) Filed: Jan. 20, 2026

(30) Foreign Application Priority Data
Jan. 30, 2025 (DE) 10 2025 103 345.5

(51) Int. Cl. H03B 5/24; H03B 5/04; H03B 5/06; H03K 3/03

(52) U.S. Cl. CPC H03B 5/24; H03B 5/04; H03B 5/06; H03K 3/0315; H03B 2200/009

(57) ABSTRACT

A voltage-controlled RC oscillator and a method for generating a clock signal using a voltage-controlled RC oscillator.

### CROSS REFERENCE

The present application claims the benefit under 35 U.S.C. § 119 of Germany Patent Application No. DE 10 2025 103 345.5 filed on Jan. 30, 2025, which is expressly incorporated herein by reference in its entirety.

### FIELD

The present disclosure relates to a voltage-controlled RC oscillator and to a method for generating a clock signal by means of a voltage-controlled RC oscillator.

### BACKGROUND INFORMATION

Ring oscillators (RO) and RC oscillators are the most common architectures for on-chip integration in the MHz range. ROs offer advantages in terms of the compromise between performance and phase noise. RC oscillators, on the other hand, are characterized by robustness, energy efficiency, and lower integration costs (see references [1-5]).

Temperature coefficient (TC) compensation is a key challenge in RC oscillators.

By using resistors with opposing TCs, an attempt is made to minimize the first-order TC and to reduce temperature dependence. However, this requires two different types of resistors ([1-5]).

Calibration with two different resistors with a negative TC can correct the nominal TC and improve accuracy over the temperature range ([1]).

Designs with dual RC frequency references, RC polyphase filters (PPFs) and digital/analog ΔΣ phase domain modulators (Φ-ΔΣM) make more precise TC compensation possible. However, these methods increase the complexity and still require complementary TC resistors ([1-5]).

[1] C. D. Ezekwe and B. E. Boser, “A Mode-Matching ΛΣ Closed-Loop Vibratory Gyroscope Readout Interface With a 0.004°/s/\sqrt{Hz} Noise Floor Over a 50 Hz Band,” in IEEE Journal of Solid-State Circuits, vol. 43, no. 12, pp. 3039-3048, Dec. 2008.

[2] Y. Zhao et al., “A Sub-0.1/h Bias-Instability Split-Mode MEMS Gyroscope with CMOS Readout Circuit,” in IEEE Journal of Solid-State Circuits, vol. 53, no. 9, pp. 2636-2650, Sept. 2018.

[3] R. Navid, T. H. Lee and R. W. Dutton, “Minimum achievable phase noise of RC oscillators,” in IEEE Journal of Solid-State Circuits, vol. 40, no. 3, pp. 630-637, March 2005.

[4] C. Gürleyük, L. Pedala, F. Sebastiano and K. A. A. Makinwa, “A CMOS Dual-RC frequency reference with ±250 ppm inaccuracy from −45° C. to 85° C.,” 2018 IEEE International Solid-State Circuits Conference—(ISSCC), San Francisco, CA, USA, 2018, pp. 54-56.

[5] Y. Ji, J. Liao, S. Arjmandpour, A. Novello, J. -Y. Sim and T. Jang, “A Second-Order Temperature-Compensated On-Chip R-RC Oscillator Achieving 7.93ppm/° C. and 3.3 pJ/Hz in −40° C. to 125° C. Temperature Range,” 2022 IEEE International Solid-State Circuits Conference (ISSCC), San Francisco, CA, USA, 2022, pp. 1-3.

[6] A. Paidimarri, D. Griffith, A. Wang, A. P. Chandrakasan and G. Burra, “120 18.5 kHz RC oscillator with comparator offset cancellation for ±0.25% temperature stability,” 2013 IEEE International Solid-State Circuits Conference Digest of Technical Papers, San Francisco, CA, USA, 2013, pp. 184-185.

In summary, existing methods for TC compensation in RC oscillators either require the use of different types of resistors or lead to increased circuit complexity. The need for complementary TC resistors continues to be a bottleneck for the development of simple and precise RC oscillators.

### SUMMARY

Voltage-controlled RC oscillators (VCOs) face the challenge of simultaneously ensuring robust functionality, low temperature drift, and good noise behavior. In particular, reducing long-term jitter sensitivity poses a significant problem.

Previous approaches to reducing jitter sensitivity and temperature drift are based on complex online or offline calibration methods.

For stabilizing the temperature drift and reducing long-term jitter, two different types of resistors are often used, which increases complexity and costs.

Existing VCO designs often fail to achieve optimal noise behavior due to jitter sensitivity.

The techniques used so far for TC compensation, such as the combination of current sources proportional to the absolute temperature (PTAT) and zero dependence on the absolute temperature (ZTAT), increase circuit design complexity.

The present disclosure addresses these shortcomings by providing a VCO that:
achieves low noise and low TC with only one resistor type,
without additional calibration for TC compensation;
reduces jitter sensitivity through noise shaping, which stabilizes the operating point independently of the jitter error in the quantizer;
allows for energy-saving operation, without impairing performance capability;
offers the possibility of further improving the TC characteristic through a combination of current sources, without excessively increasing complexity.

The present disclosure makes possible a VCO that is simultaneously robust, temperature-stable, and low-noise, without the complexity and costs of existing solutions.

The new voltage-controlled RC oscillator (RC VCO) according to the present disclosure offers crucial advantages for integration into power-saving phase-locked loops (PLLs) of sensor systems. The design ensures reliable operation even with varying supply and reference voltages, which increases the robustness of the overall system.

The use of a single reference resistor and the elimination of offline TC calibration after the initial room temperature calibration make a compact and scalable architecture possible. This reduces the complexity, chip area, and costs in comparison to conventional VCOs, which require multiple resistors and complex calibration methods.

The VCO is specifically designed for use in energy-saving applications, making it ideal for mobile and battery-powered sensor systems.

Further advantages can be found in the figures and the disclosure herein.

### BRIEF DESCRIPTION OF THE DRAWINGS

FIG. 1A shows a circuit of a voltage-controlled RC oscillator with jitter reduction, according to an example embodiment of the present disclosure.

FIG. 1B shows a timing diagram of a voltage-controlled RC oscillator with jitter reduction, according to an example embodiment of the present disclosure.

FIG. 2 shows a detailed circuit diagram of a voltage-controlled RC oscillator with feedforward load compensation and a startup ring oscillator, according to an example embodiment of the present disclosure.

### DETAILED DESCRIPTION OF EXAMPLE EMBODIMENTS

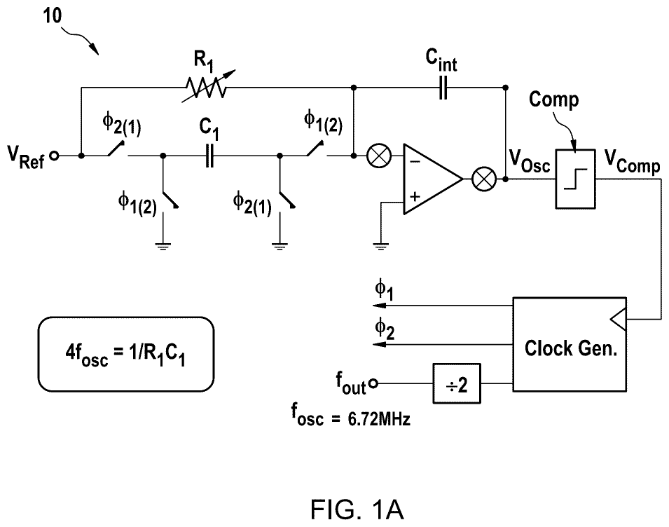

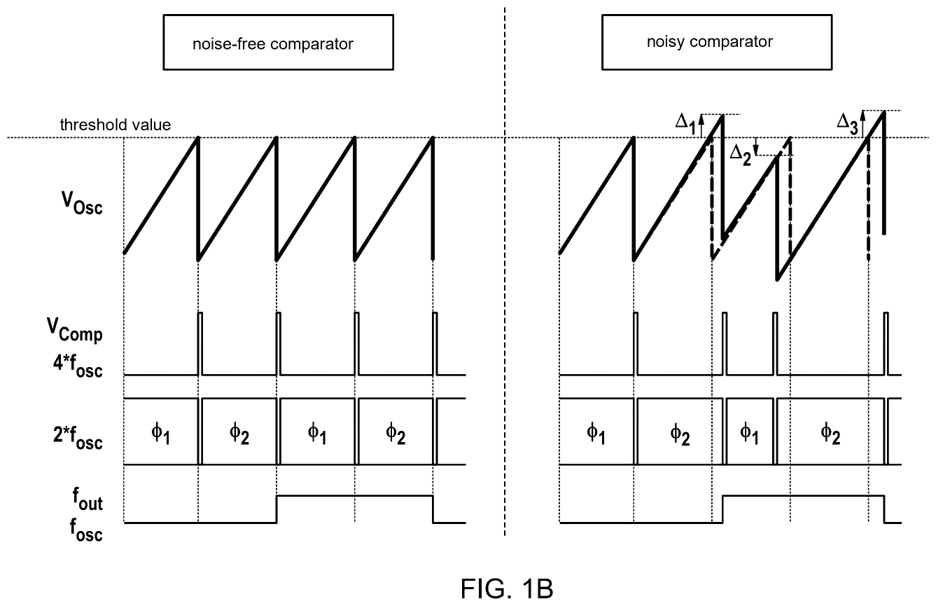

FIG. 1A shows a circuit 10 and FIG. 1B shows timing diagrams of a voltage-controlled RC oscillator with jitter reduction. The circuit has an input for a reference voltage VRef. A resistor R1 and a capacitor C1 form an RC network. R1 is powered by VRef and generates a current that is proportional to VRef. C1 is controlled via switches driven by the phase signals Φ1 and Φ2. The current through R1 is integrated by an operational amplifier with an integration capacitor Cint. The output of the operational amplifier Vosc generates a sawtooth voltage. The output Vosc is connected to a comparator Comp. Vosc is compared with an output of the comparator VComp, the threshold value of which is represented by a dashed line in the timing diagrams. The output

of the comparator controls a clock generator Clock Gen., which generates the phase signals Φ1 and Φ2. The output clock fout is divided by a frequency divider.

The timing diagrams in FIG. 1B show the behavior of the oscillator with a noise-free comparator (left diagram) and a noisy comparator (right diagram).

The output voltage Vosc of the operational amplifier rises linearly and then drops abruptly when the comparator switches.

The output VComp of the comparator Comp changes its state when Vosc reaches the threshold value. With a noisy comparator, the switching times are slightly shifted due to the noise.

The phase signals Φ1 and Φ2 control the switches for the capacitor C1. The diagrams 4*fosc and 2*fosc show the frequencies, which are four times and twice as high, respectively, as the oscillator frequency fosc.

The representation fout shows the output frequency.

The representation fosc shows the oscillator frequency fosc.

In the representation with the noisy comparator, Δ1 and Δ3 show the time shift of the switching times due to the noise.

The timing diagrams illustrate how the noise of the comparator causes jitter in the output signal, and how the architecture of the oscillator reduces this jitter. The constant charge removal and the frequency division minimize the influence of the high-frequency jitter.

The sampling capacitor C1 is charged with the reference voltage VRef. At the same time, the input resistor R1, which is also powered by VRef, generates a constant current. This current is integrated by the operational amplifier integrator, resulting in a linearly increasing voltage ramp at the output of the operational amplifier Vosc.

The comparator monitors the output voltage Vosc of the integrator. The comparator switches as soon as Vosc reaches a defined threshold value.

The switching of the comparator controls a capacitor Cint. This capacitor transfers the charge stored in C1 to the integrator with reversed polarity. This causes the output voltage Vosc of the integrator to drop abruptly.

The charging and discharging process repeats continuously. The period of the oscillator, i.e., the time that the current through R1 needs to replenish the charge discharged by the Cint, is primarily determined by the time constant R1*C1. It is, to a first approximation, independent of VRef and the capacitance of the integration capacitor Cint.

Noise in the comparator can lead to premature or delayed detection of the threshold value, causing jitter in the oscillator period. However, since a constant amount of charge is removed by the Cint in each cycle, the voltage ramp Vosc always returns to the same starting point despite the comparator noise. This prevents the period fluctuations caused by comparator noise from accumulating over time. The jitter spectrum therefore has a high-pass characteristic.

A subsequent division by 2, implemented by means of an FIR filter with two taps of equal weighting, eliminates the high-frequency jitter components from the final output clock. This results in a more stable and lower-noise output signal.

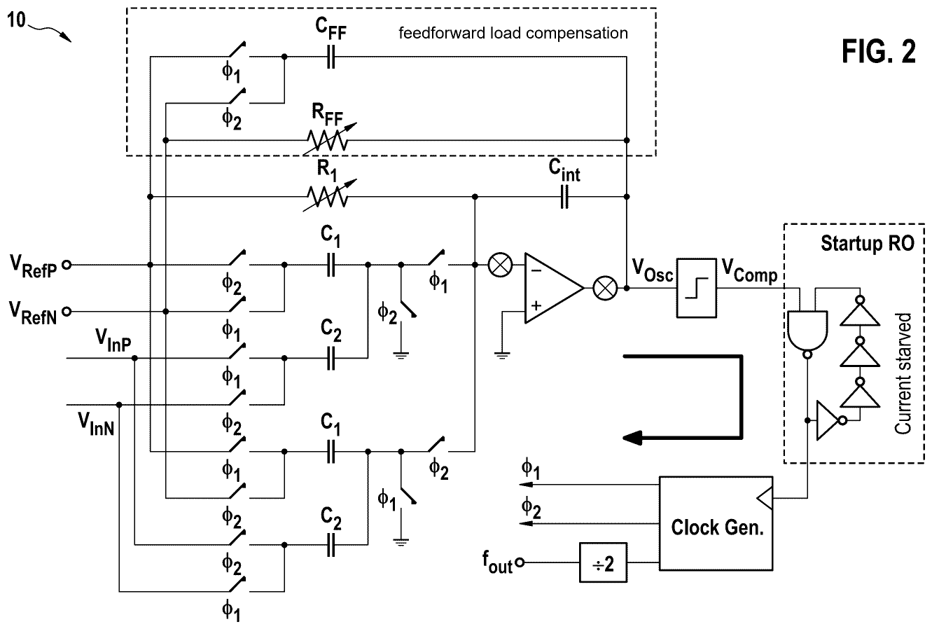

FIG. 2 shows a detailed circuit diagram 10 of a voltage-controlled RC oscillator with feedforward load compensation and a startup ring oscillator RO.

The voltage-controlled RC oscillator has differential reference voltage inputs VRefp, VRefN and differential input voltages Vinp, VinN, which control the oscillator frequency.

Three capacitors C1, C2, C3 are connected to the inputs and the operational amplifier via switches. The switches are controlled by the phase signals Φ1 and Φ2, which allow differential switching of the capacitors. C1 is connected to Vinp and VinN, C2 to VinN and ground, and C3 to Vinp and ground.

R1 is the main timing resistor that determines the charging/discharging current for the capacitors. RFF and CFF form an RC network for feedforward load compensation, which compensates for the effects of the load capacitance at the output of the operational amplifier.

Similarly to FIG. 1A, the operational amplifier integrates the current through R1 and generates a sawtooth output voltage Vosc. Cint is the integration capacitor.

Vosc is monitored by a comparator VComp, which switches when Vosc reaches a certain threshold value.

The output of the comparator controls a clock generator Clock Gen., which generates the phase signals Φ1 and Φ2. These signals control the switches for the capacitor bank and thus the charge/discharge cycle.

The output clock fout is divided by a frequency divider.

The startup RO serves to bring the voltage-controlled RC oscillator quickly into a stable operating state when switched on. It generates an initial clock signal, which starts the voltage-controlled RC oscillator before it itself transitions into a stable oscillation state.

The RO comprises an odd number of inverters arranged in a ring circuit. The note “Current starved” indicates a power-saving implementation.

The RO is deactivated as soon as the voltage-controlled RC oscillator oscillates stably.

The combination of the voltage-controlled RC oscillator, feedforward load compensation, and the startup RO makes a robust, precise, and fast-starting oscillator possible. The differential architecture improves interference immunity. The feedforward compensation increases the stability and accuracy of the oscillator frequency.

The center frequency of the voltage-controlled RC oscillator is set by an N-bit trimming of R1. This allows for a rough setting of the frequency.

The input voltage Vin finely controls the oscillator frequency in that it is sampled via the sampling capacitors C1 (reference voltage VRef) and C2 (input voltage Vin). The ratio of the charges Q1 (VRef*C1) and Q2 (Vin*C2) determines the control range of the voltage-controlled RC oscillator.

The reference and control capacitors are divided into two halves and operate with complementary clocks Φ1, Φ2. This balances the capacitive load at the virtual ground point of the integrator and reduces the load on the operational amplifier.

A comparator detects the zero crossing at the output of the integrator and triggers the clock generator Clock Gen.

The frequency of the RO is chosen such that it starts the voltage-controlled RC oscillator but does not cause any interference during normal operation.

A feedforward path, comprising RFF and CFF, compensates for the load at the integrator output and reduces the demands on the operational amplifier.

Three different biasing methods for the OTA are implemented in order to optimize the TC of the oscillator:
ZTAT (zero temperature coefficient): provides stable gm at low temperatures.
PTAT (proportional to absolute temperature): provides stable gm at high temperatures.
combination of ZTAT and PTAT: combines the advantages of the two methods for improved TC across the entire temperature range.

This architecture makes possible a robust, temperature-stable, and precise VCO with low jitter, making it suitable for use in various applications.

What is claimed is:

1. A voltage-controlled RC oscillator (VCO), comprising:
an integrator including an integration capacitor;
a reference resistor configured to generate a reference current;
a first sampling capacitor configured to sample a reference voltage;
at least one second sampling capacitor configured to sample an input control voltage;
a comparator configured to generate an output signal depending on an output voltage of the integrator;
a clock generator configured to generate clock phase signals depending on the output signal of the comparator, wherein the clock phase signals are used to control the sampling of the reference voltage and of the input control voltage;
a frequency divider; and
an auxiliary oscillator that is activated when the output of the integrator exceeds a predetermined threshold value for a predetermined time;
wherein the reference resistor and the first sampling capacitor and the at least one second sampling capacitor are connected in such a way that the VCO is robust against fluctuations in a supply voltage and the reference voltage.

2. The voltage-controlled RC oscillator according to claim 1, wherein the first capacitor and the at least one second capacitory are divided into two groups, wherein each group is operated with complementary clock phase signals to balance capacitive loads on the integrator.

3. The voltage-controlled RC oscillator according to claim 1, further comprising:
feedforward load compensation including a compensation resistor and a compensation capacitor.

4. The voltage-controlled RC oscillator according to claim 1, wherein the reference resistor is digitally trimmable in order to set a center frequency of the VCO.

5. The voltage-controlled RC oscillator according to claim 1, wherein the auxiliary oscillator is a ring oscillator.

6. The voltage-controlled RC oscillator according to claim 1, wherein the voltage-controlled RC oscillator includes temperature compensation with at least one of the following biasing methods for an operational amplifier of the integrator:
a temperature-independent current source;
a temperature-proportional current source;
a combination of temperature-independent current sources and temperature-proportional current sources.

7. The voltage-controlled RC oscillator according to claim 1, wherein the voltage-controlled RC oscillator uses chopping with and oscillator frequency in order to reduce 1/f noise.

8. A method for generating a clock signal using a voltage-controlled RC oscillator (VCO), comprising the following steps:
integrating a reference current, which flows through a reference resistor, using an integrator to generate a sawtooth output voltage;
sampling a reference voltage using a first sampling capacitor and sampling an input control voltage using at least one second sampling capacitor using clock phase signals;
comparing the output voltage of the integrator with a threshold value using a comparator;
generating clock phase signals by a clock generator depending on an output signal of the comparator;
dividing the clock phase signals generated by the clock generator, using a frequency divider to generate an output clock signal;
activating an auxiliary oscillator when the output voltage of the integrator exceeds a predetermined threshold value for a predetermined time;
wherein the method increases the robustness of the VCO against fluctuations in a supply voltage and the reference voltage.

9. The method according to claim 8, wherein the sampling of the reference voltage and the sampling of the input control voltage is carried out with two groups of sampling capacitors, wherein each group is operated with complementary clock phase signals.

10. The method according to claim 8, further comprising:
compensating loads at an output of the integrator by means of feedforward load compensation.

11. The method according to claim 8, further comprising: digitally trimming the reference resistor to set a center frequency of the VCO.

12. The method according to claim 8, wherein the auxiliary oscillator is a ring oscillator.

13. The method according to claim 8, further comprising:
compensating for temperature influences by biasing an operational amplifier of the integrator using at least one of the following methods:
using a temperature-independent current source;
using a temperature-proportional current source;
using a combination of temperature-independent current sources and temperature-proportional current sources.

14. The method according to claim 8, further comprising:
chopping with an oscillator frequency in order to reduce 1/f noise.
